(19) United States
(12) Patent Application Publication
(10) Pub. No.: US 2025/0294679 A1
(43) Pub. Date: Sep. 18, 2025

(54) WIRING SUBSTRATE AND METHOD FOR MANUFACTURING WIRING SUBSTRATE

(71) Applicant: IBIDEN CO., LTD., Ogaki (JP)

(72) Inventors: Yasuki KIMISHIMA, Ogaki (JP); Ryo KAWAUCHI, Ogaki (JP); Kazuki KAJIHARA, Ogaki (JP)

(73) Assignee: IBIDEN CO., LTD., Ogaki (JP)

(21) Appl. No.: 19/073,475

(22) Filed: Mar. 7, 2025

(30) Foreign Application Priority Data
Mar. 13, 2024 (JP) 2024-039252

(51) Int. Cl. H05K 1/11; H05K 3/42

(52) U.S. Cl. CPC H05K 1/116; H05K 3/423; H05K 2201/09454

(57) ABSTRACT

A wiring substrate includes a conductor layer including a via land, a conductor film formed on the via land of the conductor layer, an insulating layer covering the conductor layer and the conductor film formed on the via land, and a via conductor formed in the insulating layer such that the via conductor is penetrating through the insulating layer and is connecting to the via land via the conductor film. A ratio of the shortest distance between an upper surface of the conductor film and an end surface of the via conductor on the opposite side with respect to an end surface connected to the conductor film to the shortest distance between an upper surface of the via land and the end surface of the via conductor on the opposite side with respect to the end surface connected to the conductor film is in the range of 0.4 to 0.7.

### CROSS-REFERENCE TO RELATED APPLICATIONS

The present application is based upon and claims the benefit of priority to Japanese Patent Application No. 2024-039252, filed Mar. 13, 2024, the entire contents of which are incorporated herein by reference.

### BACKGROUND OF THE INVENTION

### Field of the Invention

The present invention relates to a wiring substrate and a method for manufacturing the wiring substrate.

### Description of Background Art

Japanese Patent Application Laid-Open Publication No. 2016-58472 describes a wiring substrate and a method for manufacturing the wiring substrate. The entire contents of this publication are incorporated herein by reference.

### SUMMARY OF THE INVENTION

According to one aspect of the present invention, a wiring substrate includes a conductor layer including a via land, a conductor film formed on the via land of the conductor layer, an insulating layer formed on the conductor layer such that the insulating layer is covering the conductor layer and the conductor film formed on the conductor layer, and a via conductor formed in the insulating layer such that the via conductor is penetrating through the insulating layer and connecting to the via land via the conductor film. The conductor layer, the conductor film and the via conductor are formed such that a ratio of the shortest distance between an upper surface of the conductor film and an end surface of the via conductor on the opposite side with respect to an end surface connected to the conductor film to the shortest distance between an upper surface of the via land and the end surface of the via conductor on the opposite side with respect to the end surface connected to the conductor film is in the range of 0.4 to 0.7.

According to another aspect of the present invention, a method for manufacturing a wiring substrate includes forming a conductor layer including a via land, forming a resist layer having an opening such that the opening exposes at least a portion of an upper surface of the via land, applying electrolytic plating on at least the portion of the upper surface of the via land such that a conductor film is formed on at least the portion of the upper surface of the via land of the conductor layer, removing the resist layer, forming an insulating layer on the conductor layer such that the insulating layer covers the conductor layer and the conductor film formed on the conductor layer, forming a through hole in the insulating layer such that the through hole penetrates through the insulating layer and exposes at least a portion of an upper surface of the conductor film, and filling the through hole with a conductor such that a via conductor is formed in the through hole. The forming the conductor film and the insulating layer includes adjusting a ratio of the shortest distance from the upper surface of the conductor film to the upper surface of the insulating layer to the shortest distance from the upper surface of the via land to the upper surface of the insulating layer to be in the range of 0.4 to 0.7.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2A is a partial enlarged view of a region (II) in FIG. 1;

FIG. 2B is a cross-sectional view illustrating another example of a wiring substrate according to an embodiment of the present invention;

FIG. 2C is a cross-sectional view illustrating yet another example of a wiring substrate according to an embodiment of the present invention;

FIG. 2D is a cross-sectional view illustrating yet another example of a wiring substrate according to an embodiment of the present invention;

FIG. 3A is a cross-sectional view illustrating an example of a method for manufacturing a wiring substrate according to an embodiment of the present invention;

FIG. 3B is a cross-sectional view illustrating an example of a method for manufacturing a wiring substrate according to an embodiment of the present invention;

FIG. 3C is a cross-sectional view illustrating an example of a method for manufacturing a wiring substrate according to an embodiment of the present invention;

FIG. 3D is a cross-sectional view illustrating an example of a method for manufacturing a wiring substrate according to an embodiment of the present invention;

FIG. 3E is a cross-sectional view illustrating an example of a method for manufacturing a wiring substrate according to an embodiment of the present invention; and

FIG. 3F is a cross-sectional view illustrating an example of a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

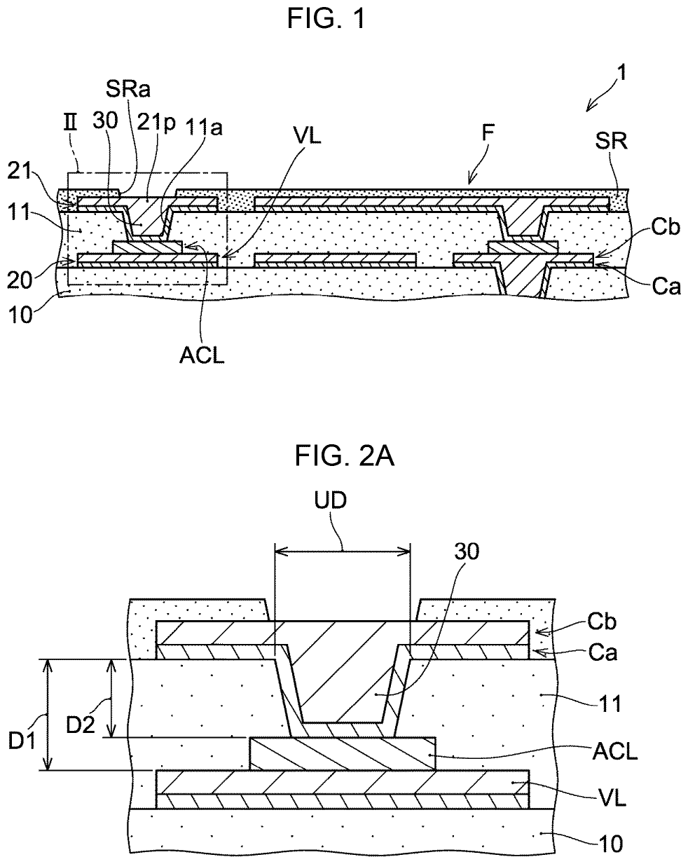

FIG. 1 partially illustrates a cross section of a wiring substrate 1, which is an example of the wiring substrate of the embodiment. The wiring substrate 1 is formed of alternately laminated insulating layers and conductor layers, and FIG. 1 illustrates some of the insulating layers and conductor layers.

In FIG. 1, among the multiple insulating layers and conductor layers that the wiring substrate 1 can have, two insulating layers (10, 11), two conductor layers (20, 21), and a solder resist layer (SR) on a surface (F) side are illustrated. The conductor layer 20 and the conductor layer 21 are connected by via conductors 30 that penetrate the insulating layer 11 in a thickness direction. In the solder resist layer (SR) that forms the surface (F) of the wiring substrate 1, openings (SRa) are formed, through which surfaces of conductor pads (21p) included in the conductor layer 21 are exposed.

The wiring substrate of the embodiment has at least the insulating layer 11, the conductor layer 20, and the via conductors 30. The number of insulating layers and conductor layers in the wiring substrate 1 is not particularly limited and can be increased or decreased as appropriate. In the illustration, the insulating layer 11 is illustrated as an uppermost insulating layer in the wiring substrate 1, and the via conductors 30 are illustrated as uppermost via conductors in the wiring substrate 1. However, the formation of the insulating layer 11, the via conductors 30, and the conductor layer 20 in the wiring substrate of the embodiment is not limited to the illustrated example. Above the insulating layer 11 and the conductor layer 21, an additional insulating layer may be laminated, and via conductors penetrating the additional insulating layer, as well as a conductor layer on the additional insulating layer, may be formed. In the description of the wiring substrate 1, the surface (F) side of the wiring substrate 1 is referred to as “upper,” an “upper side,” an “outer side,” or simply “outer.” Similarly, for each component forming the wiring substrate 1, a side where the surface (F) is formed is also referred to as “upper,” an “upper side,” an “outer side,” or simply “outer.”

The surface (F) of the illustrated wiring substrate 1 can be formed as a component mounting surface on which an external electronic component such as a semiconductor element is mounted. A surface (not illustrated) of the wiring substrate 1 on the opposite side with respect to the surface (F) is formed as a connection surface used for connecting to a motherboard of an electronic device, or a package substrate of a semiconductor device having a laminated structure, or the like. The surface (F) of the wiring substrate 1 illustrated in FIG. 1 is formed of a surface of the solder resist layer (SR) and the surfaces of the conductor pads (21p) exposed in the openings (SRa) of the solder resist layer (SR).

The conductor layer 20 is formed in contact with an upper surface of the insulating layer 10. The conductor layer 20 includes via lands (VL) that connect to the via conductors 30 formed above via lands (VL). The via lands (VL) formed in the conductor layer 20 are electrically connected to the conductor layer 21 on the opposite side with respect to the insulating layer 11 via the via conductors 30 formed in the insulating layer 11. The via conductors 30 are formed by conductors filled in through holes (11a) that penetrate the insulating layer 11. The via conductors 30 each have a tapered shape that is reduced in diameter from the surface (F) toward the opposite side (lower side). However, but the shape of each of the via conductors 30 is not limited to this. The via conductors 30 may each have a shape that is reduced in diameter toward the surface (F), or may each be formed in a cylindrical shape that has a uniform diameter in the thickness direction of the insulating layer 11 and is substantially orthogonal to the conductor layer 20. Although the term “diameter” is used, a planar shape of each of the through holes (11a) or the via conductors 30 is not necessarily limited to a circular shape. The term “diameter” refers to a longest distance between the two points on an outer circumference in a horizontal cross section of each of the through holes (11a) or the via conductors 30. Further, for convenience, the term “reduced in diameter” is used. However, the term “reduced in diameter” means that the longest distance between two points on an outer circumference in a horizontal cross section of each of the via conductors 30 is reduced.

In the wiring substrate of the embodiment, a conductor film (ACL) is formed on the via lands (VL) of the conductor layer 20. The via lands (VL) of the conductor layer 20 and the via conductors 30 are connected via the conductor film (ACL). As illustrated, the conductor film (ACL) can be formed only on the via lands (VL) in conductor patterns of the conductor layer 20.

The insulating layers (10, 11) of the wiring substrate 1 are formed using any insulating resin, such as an epoxy resin. A polyimide resin, a BT resin (bismaleimide-triazine resin), a polyphenylene ether resin, a phenol resin or the like can also be used. The insulating layers (10, 11) may each contain an inorganic filler such as silica. In the wiring substrate 1 in the illustrated example, the insulating layers (10, 11) do not each contain a core material. However, when necessary, the insulating layers (10, 11) may each contain a core material such as a glass fiber or an aramid fiber. The multiple insulating layers that can form the wiring substrate 1 may be respectively formed of different materials or may all be formed of the same material. The solder resist layer (SR) is formed using, for example, a photosensitive polyimide resin or epoxy resin, or the like.

The conductor layers (20, 21), the conductor film (ACL), and the via conductors 30 can be formed using any material having suitable conductivity, such as copper. The conductor layers (20, 21) and the via conductors 30 can each be formed, for example, by a sputtering film, an electroless plating film, an electrolytic plating film, or a combination of these. In the illustrated example, the conductor layers (20, 21) are each formed to have a two-layer structure including of a metal film layer (Ca), which can be, for example, an electroless copper plating film, and a plating film layer (Cb), which can be, for example, an electrolytic copper plating film. However, the structure of each of the conductor layers (20, 21) forming the wiring substrate 1 is not limited to the multilayer structure illustrated in FIG. 1. For example, the conductor layers (20, 21) may each be formed to have a three-layer structure including a copper foil, an electroless copper plating film layer, and an electrolytic copper plating film layer. Further, the conductor layers (20, 21) may each be formed to have a single-layer structure including an electroless plating film.

As illustrated, the via conductors 30 can be integrally formed with the metal film layer (Ca) and the plating film layer (Cb) that form the conductor layer 21. In the illustrated example, the via conductors 30 are so-called filled vias that fill the through holes (11a), and are formed of the metal film layer (Ca), which covers an inner surface (a bottom surface and an inner wall surface) of each of the through holes (11a), and the plating film layer (Cb). Further, it is also possible that the via conductors 30 are formed to each have a single-layer structure including an electroless plating film.

The conductor film (ACL) formed on the via lands (VL) is formed as an electrolytic plating film layer by electrolytic plating on the conductor layer 20. The conductor film (ACL) can be formed of a single layer, specifically an electrolytic plating film. The conductor film (ACL) is preferably formed of the same conductor material as the conductor material that forms the plating film layer (Cb) that forms the conductor layer 20.

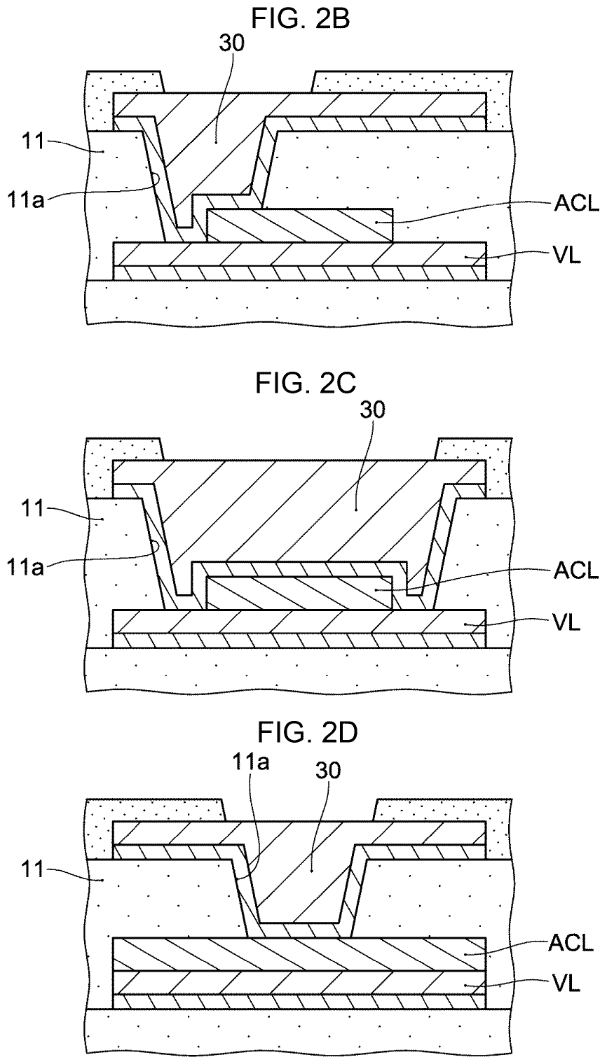

Next, with reference to FIG. 2A, structures of a via land (VL), the conductor film (ACL) on the via land (VL), and a via conductor 30 in the wiring substrate of the embodiment are described in detail. FIGS. 2A-2D are each an enlarged view of a region (II) surrounded by a one-dot chain line in FIG. 1.

In the example illustrated in FIG. 2A, an entire bottom surface of the through hole (11a) is formed of an upper surface of the conductor film (ACL). An entire bottom part of the via conductor 30 is directly connected to the upper surface of the conductor film (ACL). The via land (VL) and the via conductor 30 are not directly connected, but are indirectly connected via the conductor film (ACL). Therefore, a depth of the via conductor 30 (dimension of the via conductor 30 in the thickness direction of the insulating layer 11) is smaller compared to a case where the via conductor 30 is directly connected to the via land (VL).

The conductor film (ACL) is formed so as to satisfy a predetermined dimensional condition with respect to a shortest distance (D1) between the upper surface of the via land (VL) and the upper surface of the via conductor 30. The “upper surface of the via conductor 30” refers to an end surface of the via conductor 30 on the opposite side with respect to an end surface connected to the upper surface of the conductor film (ACL), among two end surfaces extending orthogonally to a depth direction of the via conductor 30. That is, the “upper surface of the via conductor 30” refers to an interface between the via conductor 30 and the conductor layer 21 along the upper surface of the insulating layer 11. In the thickness direction of the insulating layer 11, the upper surface of the via conductor 30 is positioned at the same level as the upper surface of the insulating layer 11. Specifically, the conductor film (ACL) is formed to a thickness such that a ratio of a shortest distance (D2) between the upper surface of the conductor film (ACL) and the upper surface of the via conductor 30 to the shortest distance (D1) between the upper surface of the via land (VL) and the end face of the via conductor 30 on the opposite side with respect to the end face connected to the conductor film (ACL) is 0.4 or more and 0.7 or less.

By forming the conductor film (ACL) with a thickness that allows the predetermined dimensional condition described above to be satisfied, a through hole (11a) having a relatively small depth can be formed. By forming a through hole (11a) with a relatively small depth, a via conductor 30 can be formed in the through hole (11a) with relatively few defects compared to when the through hole (11a) is relatively deep. When a through hole (11a) is relatively deep, a void may be likely generated in a process of forming a via conductor 30 (particularly in the formation of the plating film layer (Cb)). Further, a downward recess may be formed in a region directly above a via conductor 30 of the conductor layer 21 formed integrally with the via conductor 30. To address such a problem, the conductor film (ACL) is formed to satisfy the predetermined dimensional condition described above, and thus, the through hole (11a) can be formed to have a relatively small depth and the via conductor 30 can be formed void-free. Further, a conductor layer 21 can be formed in which a recess in a region directly above a via conductor 30 is suppressed.

From a point of view of suppressing a void in the via conductor 30 as described above, the conductor film (ACL) is preferably formed to have a thickness such that the shortest distance between the upper surface of the conductor film (ACL) and the upper surface of the via conductor 30 is 20 μm or more and 35 μm or less. Further, from the same point of view, the via conductor 30 preferably has a diameter (UD) of 50 μm or more and 70 μm or less. Here, the “diameter of the via conductor 30” means a longest distance between two points on a peripheral edge of the upper surface of the via conductor 30 in a planar view.

Further, from a point of view of void suppression as described above, the via conductor 30 is preferably formed to have an aspect ratio ((the shortest distance (D2) between the upper surface of the conductor film (ACL) and the upper surface of the via conductor 30)/(the diameter (UD) of the via conductor 30)) of 1.4 or more and 2.5 or less. For example, as described above, when the diameter (UD) of the via conductor 30 is 50 μm or more and 70 μm or less, the shortest distance (D1) from the upper surface of the via land (VL) to the upper surface of the via conductor 30 is about 40 μm to 50 μm, and the thickness of the conductor film (ACL) is about 15 μm to 20 μm. Therefore, the depth of the via conductor 30 (the shortest distance (D2) between the upper surface of the conductor film (ACL) and the upper surface of the via conductor 30) can be about 20 μm to 35 μm.

Next, with reference to FIG. 2B, an example differing from the one illustrated in FIG. 2A is described regarding structures related to connections between the via conductor 30, the via land (VL), and the conductor film (ACL). In FIG. 2A, an example is illustrated in which the via conductor 30 is directly connected to the conductor film (ACL) and indirectly connected to the via land (VL) via the conductor film (ACL). However, in the example illustrated in FIG. 2B, the via conductor 30 is directly connected to the conductor film (ACL) and the via land (VL). Specifically, the through hole (11a) exposes the upper surface of the via land (VL) and the side and upper surfaces of the conductor film (ACL) at the bottom surface of the through hole (11a). That is, the bottom part of the via conductor 30 is directly connected to the upper surface of the via land (VL) and the side and upper surfaces of the conductor film (ACL). In the example illustrated in FIG. 2B, as well as in examples illustrated in FIGS. 2C and 2D to be subsequently referenced, structures other than those related to the connections between the via conductor 30, the via land (VL), and the conductor film (ACL) are the same as those described with reference to FIG. 2A, and thus, their descriptions are omitted.

In the example illustrated in FIG. 2B, the via land (VL) is directly connected to the conductor film (ACL) and the via conductor 30, the conductor film (ACL) is directly connected to the via land (VL) and the via conductor 30, and the via conductor 30 is directly connected to the via land (VL) and the conductor film (ACL). In addition to the void suppression in the via conductor 30 described above, it is thought that more reliable connection structures, less prone to delamination, may be achieved by the direct connections between the via conductor 30, the conductor film (ACL), and the via land (VL).

Next, with reference to FIG. 2C, a modified example of the example illustrated in FIG. 2B is described, regarding the structures related to the via conductor 30, the via land (VL), and the conductor film (ACL). In the example illustrated in FIG. 2C, the entire upper and side surfaces of the conductor film (ACL) are directly connected to the via conductor 30. Further, the via conductor 30 is directly connected to the via land (VL) across an entire surrounding region of the conductor film (ACL). According to such structures, in addition to the void suppression in the via conductor 30 described above, it is thought that occurrence of delamination in the connections between the via conductor 30, the conductor film (ACL), and the via land (VL) may be more effectively suppressed.

Next, with reference to FIG. 2D, an example differing from the one illustrated in FIG. 2A is described regarding the structures related to the via conductor 30, the via land (VL), and the conductor film (ACL). In the example illustrated in FIG. 2D, similar to the example illustrated in FIG. 2A, the entire bottom part of the via conductor 30 is directly connected to the upper surface of the conductor film (ACL). However, it differs from the example illustrated in FIG. 2A in that the entire upper surface of the via land (VL) is covered by the conductor film (ACL). In this way, by forming the conductor film (ACL) over a relatively wide area, during formation of the via conductor 30 (specifically, during drilling of the through hole (11a)), the possibility of a condition occurring where the upper surface of the conductor film (ACL) cannot be exposed at the bottom surface of the through hole (11a) may be reduced, and therefore, the void suppression in the via conductor 30 described above may be more effectively achieved.

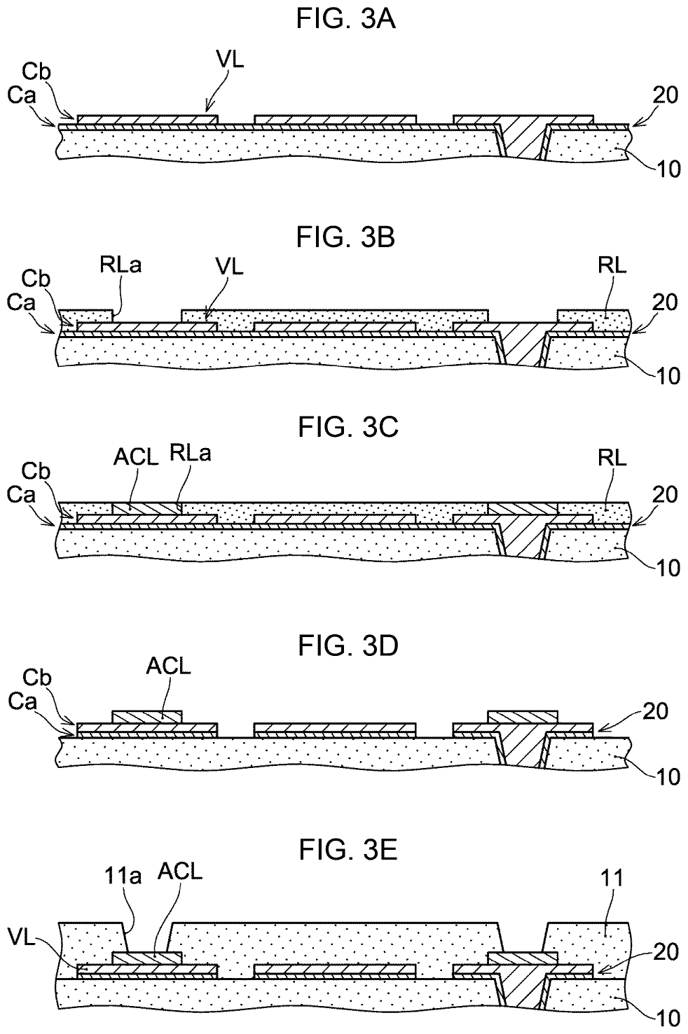

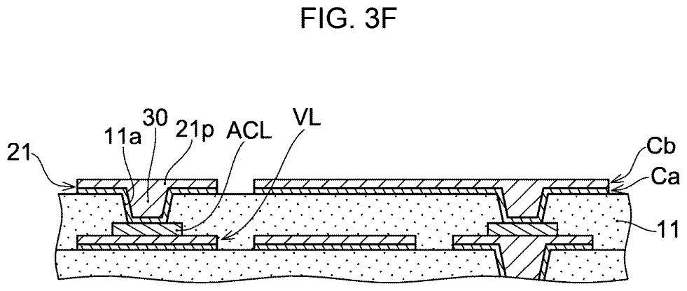

In the following, using the wiring substrate 1 illustrated in FIG. 1 as an example, a method for manufacturing the wiring substrate of the embodiment is described with reference to FIGS. 3A to 3F. In FIGS. 3A to 3F, similar to FIG. 1, the wiring substrate 1 is not illustrated in its entirety; only a partial cross section of the surface (F) side of the wiring substrate 1 is illustrated. In the following description, similar to the description of the wiring substrate 1 presented above, for each structural element of the wiring substrate 1, a side where the surface (F) of the wiring substrate 1 is formed is also referred to as “upper,” an “upper side,” an “outer side,” or simply “outer.”

First, for example, a wiring substrate may be prepared for which a manufacturing process has been completed up to the lamination of the insulating layer 10, using a method for manufacturing a wiring substrate based on a build-up method, in which one or more pairs of insulating layers and conductor layers are laminated. The conductor layer 20 having patterns including the via lands (VL) is laminated on the insulating layer 10 of the prepared wiring substrate to have, for example, a two-layer structure including the metal film layer (Ca) and the plating film layer (Cb), and the state illustrated in FIG. 3A is formed. The metal film layer (Ca) can be formed, for example, as an electroless copper plating film covering the entire upper surface of the insulating layer 10 by electroless copper plating, and the plating film layer (Cb) can be formed, for example, as an electrolytic copper plating film by electrolytic copper plating using the metal film layer (Ca) as a power feeding layer. In the illustrated state, among the metal film layer (Ca) and plating film layer (Cb) that form the conductor layer 20, the plating film layer (Cb) is formed to have patterns to be included in the conductor layer 20, and the metal film layer (Ca) covers the entire upper surface of the insulating layer 10 and is exposed from the patterns of the plating film layer (Cb).

Next, as illustrated in FIG. 3B, a resist film (RL) is formed on the surface of the conductor layer 20 (including the upper and side surfaces of the plating film layer (Cb) and the upper surface of the metal film layer (Ca) exposed from the patterns of the plating film layer (Cb)). The resist film (RL) is formed to have openings (RLa) corresponding to positions where the conductor film (ACL) (see FIG. 1) is to be formed. The resist film (RL) can be formed, for example, by forming a resin layer containing a photosensitive polyhydroxyether resin, epoxy resin, phenol resin, or polyimide resin, and then performing exposure and development using a mask with opening patterns corresponding to the patterns of the openings (RLa).

Next, as illustrated in FIG. 3C, the conductor film (ACL) is formed in the openings (RLa) of the resist film (RL), for example, by electrolytic plating using the conductor layer 20 as a power feeding layer. In the formation of the conductor film (ACL), electrolytic plating using the same conductive material as the plating film layer (Cb) of the conductor layer 20 can be performed.

Next, the resist film (RL) is removed. The side surface of the conductor film (ACL) and the upper surface of the conductor layer 20 are exposed by the removal of the resist film (RL). The metal film layer (Ca) exposed by the removal of the resist film (RL) is removed by etching, and the upper surface of the insulating layer 10 is exposed from the patterns of the conductor layer 20. The state illustrated in FIG. 3D is formed. The metal film layer (Ca) is removed by etching after the formation of the conductor film (ACL). That is, the formation of the plating film layer (Cb) and the formation of the conductor film (ACL) can be performed by electrolytic plating using the common metal film layer (Ca) as a power feeding layer.

Next, as illustrated in FIG. 3E, the insulating layer 11 is formed to cover the surface (including the upper and side surfaces) of the conductor film (ACL), the surface (including the upper and side surfaces) of the conductor layer 20, and the upper surface of the insulating layer 10 exposed from the patterns of the conductor layer 20. The insulating layer 11 can be formed by thermocompression bonding any insulating resin such as polyimide resin, BT resin (bismaleimide-triazine resin), polyphenylene ether resin, or phenol resin, which has been molded into a film-like shape. Next, the through holes (11a) that penetrate the insulating layer 11 are formed at formation positions of the via conductors 30 (see FIG. 1) in the insulating layer 11, for example, by irradiation with laser such as carbon dioxide laser or YAG laser. The through holes (11a) are formed so as to expose the upper surface of the conductor film (ACL) at the bottom surface of each of the through holes (11a).

In the formation of the conductor film (ACL) described with reference to FIG. 3C, and in the formation of the insulating layer 11 described with reference to FIG. 3E, the thickness of the conductor film (ACL) and the thickness of the insulating layer 11 are adjusted to satisfy the predetermined dimensional condition. Specifically, the thickness of the conductor film (ACL) and the thickness of the insulating layer 11 are adjusted such that the ratio of the shortest distance between the upper surface of the conductor film (ACL) and the upper surface of the insulating layer 11 to the shortest distance between the upper surface of the conductor layer 20 and the upper surface of the insulating layer 11 is 0.4 or more and 0.7 or less. That is, the depth of the through holes (11a) that penetrate the insulating layer 11 and expose the conductor film (ACL) at the bottom surfaces (the dimension of the insulating layer 11 in the thickness direction) is made smaller compared to the case where the upper surface of the conductor layer 20 (the upper surface of the via lands (VL)) is exposed at the bottom surfaces, in accordance with the above-described condition satisfied by the conductor film (ACL) and the insulating layer 11.

For example, in the formation of the conductor film (ACL) and the formation of the insulating layer 11, the shortest distance between the upper surface of the conductor film (ACL) and the upper surface of the insulating layer 11 is adjusted to be 20 μm or more and 35 μm or less. In the formation of the through holes (11a) described with reference to FIG. 3E, the diameter of each of the through holes (11a) (the longest distance between two points on the peripheral edge of each of the through holes (11a) on the upper surface of the insulating layer 11) can be made to be 50 μm or more and 70 μm or less.

Next, as illustrated in FIG. 3F, the conductor layer 21 that covers the via conductors 30 in the through holes (11a) and the upper surface of the insulating layer 11 is integrally formed. The metal film layer (Ca) is formed over the inner surfaces (including the bottom and side wall surfaces) of the through holes (11a) and the entire upper surface of the insulating layer 11, for example, by electroless copper plating. Subsequently, a plating resist for electrolytic plating having openings according to the conductor patterns to be formed in the conductor layer 21 is formed on the metal film layer (Ca), and the plating film layer (Cb) is formed in the openings, for example, by electrolytic copper plating.

The via conductors 30 are formed by forming the plating film layer (Cb) on the metal film layer (Ca) covering the inner walls of the through holes (11a) exposed in the openings of the plating resist. As described above, the thicknesses of the conductor film (ACL) and the insulating layer 11 are formed to satisfy the predetermined dimensional condition. Therefore the depth of the through holes (11a) exposed in the opening is relatively small. Therefore, it is thought that a void is unlikely to be formed in the formation of the plating film layer (Cb) in the through holes (11a). In addition, it is thought that a recess is unlikely to be formed in a region directly above a via conductor 30 in the conductor layer 21, which is integrally formed with the via conductors 30.

Subsequently, the metal film layer (Ca) is exposed by the removal of the plating resist, and the exposed metal film layer (Ca) is removed by etching to expose the upper surface of the insulating layer 11. The conductor layer 21 including the conductor pads (21p) is formed.

Next, the solder resist layer (SR) is formed by laminating a photosensitive epoxy resin or polyimide resin layer on the surfaces of the conductor layer 21 and the insulating layer 11. In the solder resist layer (SR), the openings (SRa) that define the conductor pads (21p) are formed by photolithography. The formation of the wiring substrate 1 is completed.

The wiring substrate of the embodiment is not limited to a wiring substrate having the structures exemplified in the drawings, or the structures or materials exemplified in the present specification. The wiring substrate of the embodiment includes at least a conductor layer including a via land, a conductor film formed on the via land, an insulating layer covering the conductor layer, and a via conductor that penetrates the insulating layer and connects to the via land via the conductor film. A ratio of a shortest distance between an upper surface of the conductor film and an upper surface of the via conductor to a shortest distance between an upper surface of the via land and the upper surface of the via conductor may be 0.4 or more and 0.7 or less. The number of insulating layers and conductor layers forming the wiring substrate is not limited. Further, for example, a plating layer including a nickel layer and a tin layer, or the like, may be formed on the surfaces of the conductor pads (21p) included in the conductor layer 21, which constitutes the surface (F).

The method for manufacturing the wiring substrate of the embodiment is not limited to the method described with reference to the drawings, and conditions, processing order, and the like of the method can be modified as appropriate. A method for manufacturing the wiring substrate of the embodiment includes: forming a conductor layer including a via land; forming a resist including an opening exposing the via land; forming a conductor film by electrolytic plating; forming an insulating layer that covers the conductor film; forming a through hole exposing an upper surface of the conductor film; and forming a via conductor in the through hole. Forming the conductor film and the insulating layer includes adjusting a ratio of a shortest distance from the upper surface of the conductor film to an upper surface of the insulating layer to a shortest distance from an upper surface of the via land to the upper surface of the insulating layer to be 0.4 or more and 0.7 or less. For example, it is also possible that after forming the conductor layer 21, a solder resist layer (SR) is not formed on the conductor layer 21, and any number of insulating layers and conductor layers are further laminated. Depending on a structure of an actually manufactured wiring substrate, some of the processes may be omitted, or other processes may be added.

Japanese Patent Application Laid-Open Publication No. 2016-58472 describes a wiring substrate and a method for manufacturing the wiring substrate. An insulating layer is formed on a conductor layer; a through hole that penetrates the insulating layer is formed in the insulating layer; and a via conductor that connects to the conductor layer is formed by filling the through hole with a conductor.

In the method for manufacturing a wiring board described in Japanese Patent Application Laid-Open Publication No. 2016-58472, it is thought that when the insulating layer is thick, the depth of the through hole increases and becomes difficult to be filled with a conductor. It is thought that a defect including a void may occur in a formed via conductor.

A wiring substrate according to an embodiment of the present invention includes: a conductor layer including a via land; a conductor film formed on the via land; an insulating layer covering the conductor layer and the conductor film; and a via conductor that penetrates the insulating layer and connects to the via land via the conductor film. A ratio of a shortest distance between an upper surface of the conductor film and an end surface of the via conductor on the opposite side with respect to an end surface connected to the conductor film to a shortest distance between an upper surface of the via land and the end surface of the via conductor on the opposite side with respect to the end surface connected to the conductor film is 0.4 or more and 0.7 or less.

A method for manufacturing a wiring substrate according to another embodiment of the present invention includes: forming a conductor layer including a via land; forming a resist layer including an opening exposing an upper surface of the via land; forming a conductor film in the opening by electrolytic plating; removing the resist layer; forming an insulating layer that covers the conductor layer and the conductor film; forming a through hole penetrating the insulating layer and exposing an upper surface of the conductor film; and forming a via conductor by filling the through hole with a conductor. Forming the conductor film and the insulating layer includes adjusting a ratio of a shortest distance from the upper surface of the conductor film to an upper surface of the insulating layer to a shortest distance from the upper surface of the via land to the upper surface of the insulating layer to be 0.4 or more and 0.7 or less.

According to an embodiment of the present invention, a high quality wiring substrate in which a defect in a via conductor is suppressed can be provided.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a conductor layer including a via land;
a conductor film formed on the via land of the conductor layer;
an insulating layer formed on the conductor layer such that the insulating layer is covering the conductor layer and the conductor film formed on the conductor layer; and
a via conductor formed in the insulating layer such that the via conductor is penetrating through the insulating layer and connecting to the via land via the conductor film,
wherein the conductor layer, the conductor film and the via conductor are formed such that a ratio of a shortest distance between an upper surface of the conductor film and an end surface of the via conductor on an opposite side with respect to an end surface connected to the conductor film to a shortest distance between an upper surface of the via land and the end surface of the via conductor on the opposite side with respect to the end surface connected to the conductor film is in a range of 0.4 to 0.7.

2. The wiring substrate according to claim 1, wherein the via conductor is formed such that the shortest distance between the upper surface of the conductor film and the end surface of the via conductor on the opposite side with respect to the end surface connected to the conductor film is in a range of 20 μm to 35 μm.

3. The wiring substrate according to claim 1, wherein the via conductor is formed such that the via conductor has a diameter in a range of 50 μm to 70 μm.

4. The wiring substrate according to claim 1, wherein the via conductor is formed such that the via conductor has an aspect ratio in a range of 1.4 to 2.5.

5. The wiring substrate according to claim 1, wherein the via conductor is formed such that an entire bottom part of the via conductor is directly connected to the upper surface of the conductor film.

6. The wiring substrate according to claim 1, wherein the via conductor is formed such that a bottom part of the via conductor is directly connected to the upper surface of the conductor film and the upper surface of the via land.

7. The wiring substrate according to claim 1, wherein the via land includes a metal film layer and a plating film layer, and the conductor film includes a plating film layer.

8. The wiring substrate according to claim 1, wherein the conductor film is formed only on the via land of the conductor layer.

9. The wiring substrate according to claim 1, wherein the conductor layer includes a metal film layer and a plating film layer, and the conductor film and the plating film layer of the conductor layer are formed of a same conductor material.

10. The wiring substrate according to claim 9, wherein the conductor material is copper.

11. The wiring substrate according to claim 2, wherein the via conductor is formed such that the via conductor has a diameter in a range of 50 μm to 70 μm.

12. The wiring substrate according to claim 2, wherein the via conductor is formed such that the via conductor has an aspect ratio in a range of 1.4 to 2.5.

13. The wiring substrate according to claim 2, wherein the via conductor is formed such that an entire bottom part of the via conductor is directly connected to the upper surface of the conductor film.

14. The wiring substrate according to claim 2, wherein the via conductor is formed such that a bottom part of the via conductor is directly connected to the upper surface of the conductor film and the upper surface of the via land.

15. The wiring substrate according to claim 2, wherein the via land includes a metal film layer and a plating film layer, and the conductor film includes a plating film layer.

16. The wiring substrate according to claim 2, wherein the conductor film is formed only on the via land of the conductor layer.

17. The wiring substrate according to claim 2, wherein the conductor layer includes a metal film layer and a plating film layer, and the conductor film and the plating film layer of the conductor layer are formed of a same conductor material.

18. A method for manufacturing a wiring substrate, comprising:
forming a conductor layer including a via land;
forming a resist layer having an opening such that the opening exposes at least a portion of an upper surface of the via land;
applying electrolytic plating on at least the portion of the upper surface of the via land such that a conductor film is formed on at least the portion of the upper surface of the via land of the conductor layer;
removing the resist layer;
forming an insulating layer on the conductor layer such that the insulating layer covers the conductor layer and the conductor film formed on the conductor layer;
forming a through hole in the insulating layer such that the through hole penetrates through the insulating layer and exposes at least a portion of an upper surface of the conductor film; and
filling the through hole with a conductor such that a via conductor is formed in the through hole,
wherein the forming the conductor film and the insulating layer includes adjusting a ratio of a shortest distance from the upper surface of the conductor film to an upper surface of the insulating layer to a shortest distance from the upper surface of the via land to the upper surface of the insulating layer to be in a range of 0.4 to 0.7.

19. The method for manufacturing a wiring substrate according to claim 18, wherein the forming the conductor layer includes forming a metal film layer and applying electrolytic plating using the metal film layer as a power feeding layer such that a plating film layer is formed on the metal film.

20. The method for manufacturing a wiring substrate according to claim 19, wherein the forming the conductor film includes applying electrolytic plating using the metal film layer as a power feeding layer.
